(19) United States
(12) Patent Application Publication
(10) Pub. No.: US 2026/0040937 A1
(43) Pub. Date: Feb. 5, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Seo In LEE, Icheon-si Gyeonggi-do (KR); Yu Jin KWON, Icheon-si Gyeonggi-do (KR); Byung Soo PARK, Icheon-si Gyeonggi-do (KR)

(73) Assignee: SK hynix Inc., Icheon-si Gyeonggi-do (KR)

(21) Appl. No.: 18/977,445

(22) Filed: Dec. 11, 2024

(30) Foreign Application Priority Data
Aug. 5, 2024 (KR) 10-2024-0103792

(51) Int. Cl. H01L 23/528; H10D 64/27

(52) U.S. Cl. CPC H01L 23/5283; H10D 64/512

(57) ABSTRACT

A semiconductor device includes a gate structure including a plurality of conductive layers alternately stacked with a plurality of insulating layers; a contact structure extending within the gate structure and electrically connected to one of the conductive layers; a plurality of second supports, each second support including a pillar having a center located within a first distance of a center of the contact structure and protrusions extending between the pillar and the plurality of conductive layers; and a plurality of first supports at least partially surrounded by the plurality of protrusions.

### CROSS-REFERENCE TO RELATED APPLICATION

The present application claims priority under 35 U.S.C. § 119(a) to Korean Patent Application No. 10-2024-0103792, filed in the Korean Intellectual Property Office on Aug. 5, 2024, which application is incorporated herein by reference in its entirety.

### BACKGROUND

### 1. Technical Field

The present disclosure relates to an electronic device, including but not limited to a semiconductor device and a method of manufacturing the semiconductor device.

### 2. Related Art

The degree of integration of a semiconductor device is mainly determined by an area occupied by a unit memory cell. As improvement in the degree of integration of a semiconductor device in a single layer on a substrate reaches a limit of forming memory cells, a three-dimensional semiconductor device that stacks memory cells on a substrate is under development. To improve the operational reliability of such a semiconductor device, various structures and manufacturing methods are also under development.

### SUMMARY

In an embodiment, a semiconductor device may include: a gate structure including a plurality of conductive layers alternately stacked with a plurality of insulating layers; a contact structure extending within the gate structure and electrically connected to one of the conductive layers; a plurality of second supports, each second support including a pillar having a center located within a first distance of a center of the contact structure and a plurality of protrusions extending between the pillar and the conductive layers; and a plurality of first supports at least partially surrounded by the plurality of protrusions.

In an embodiment, a semiconductor device may include: a gate structure including a plurality of conductive layers alternately stacked with a plurality of insulating layers; a contact structure extending within the gate structure and electrically connected to one of the plurality of conductive layers; a plurality of second supports, each of the plurality of second supports including a pillar spaced apart from the contact structure by a first distance and including a plurality of protrusions extending between the pillar and the plurality of conductive layers, wherein the pillar extends through the gate structure and the plurality of protrusions extends to a second distance from a center of the pillar; and a plurality of first supports located within the second distance of one of the plurality of second supports.

In an embodiment, a method of manufacturing a semiconductor device may include: forming a stack including a plurality of first material layers alternately stacked with a plurality of second material layers; forming a first support extending at least partially through the stack; forming a sacrificial contact structure extending through the stack; forming a first opening extending through the stack; forming a plurality of second openings by etching the a plurality of first material layers through the first opening, the second openings exposing the first support and the sacrificial contact structure; and forming a second support in the first opening and the plurality of second openings.

In an embodiment, a method of manufacturing a semiconductor device may include: forming a stack including a plurality of first material layers alternately stacked with a plurality of second material layers; forming a plurality of first openings extending through the stack; forming a plurality of second openings extending through the stack, wherein centers of the plurality of second openings are located at a first distance from a point on the stack, wherein the plurality of second openings are spaced apart; forming a plurality of first supports, one first support disposed in each of the first openings; forming a sacrificial contact structure extending at least partially through the stack and centered at the point on the stack; forming a plurality of third openings by etching the plurality of first material layers through the plurality of second openings, the plurality of third openings exposing the plurality of first supports and the sacrificial contact structure; and forming a plurality of second supports, one second support disposed in each of the second openings and one set of the plurality of third openings.

### BRIEF DESCRIPTION OF THE DRAWINGS

FIG. 1A to FIG. 1D are diagrams illustrating the structure of a semiconductor device in accordance with an embodiment.

FIG. 2A and FIG. 2B are diagrams illustrating the structure of a semiconductor device in accordance with an embodiment.

FIG. 3 is a diagram illustrating the structure of a semiconductor device in accordance with an embodiment.

FIG. 4 is a diagram illustrating the structure of a semiconductor device in accordance with an embodiment.

FIG. 5A to FIG. 5E are diagrams illustrating a semiconductor device as formed utilizing a method of manufacturing a semiconductor device in accordance with an embodiment.

FIG. 6A, FIG. 6B, FIG. 7A, FIG. 7B, FIG. 8A, FIG. 8B, FIG. 9A, FIG. 9B, FIG. 10A, FIG. 10B, FIG. 11A and FIG. 11B are diagrams illustrating a semiconductor device as formed utilizing a method of manufacturing a semiconductor device in accordance with an embodiment.

FIG. 12 is a configuration diagram of a semiconductor device in accordance with an embodiment.

FIG. 13 is a configuration diagram of a semiconductor device in accordance with an embodiment.

### DETAILED DESCRIPTION

Various embodiments are directed to a semiconductor device having a stable structure and improved reliability as well as other characteristics and a method of manufacturing the semiconductor device.

By stacking memory cells in three dimensions, the degree of integration of a semiconductor device may be improved. A semiconductor device having a stable structure and improved reliability may result.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

When one element is identified as “connected” to another element, the elements may be connected directly or through an intervening element between the elements. When two elements are identified as “directly connected,” one element is directly connected to the other element without an intervening element between the two elements. Terms such as “bottom,” “below,” “over,” “on,” “inside,” “outside,” “upper,” “high,” “column,” “row,” “level,” “outermost,” “vertical,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

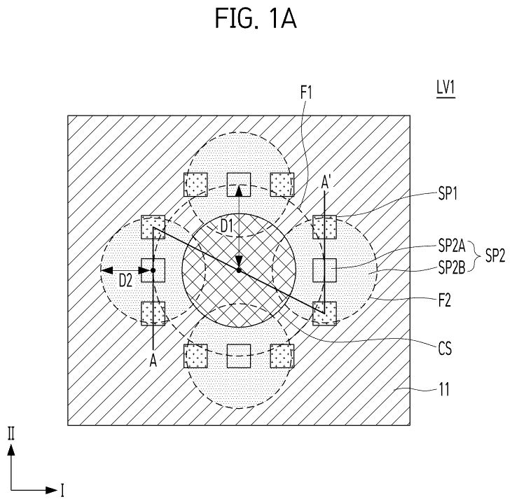

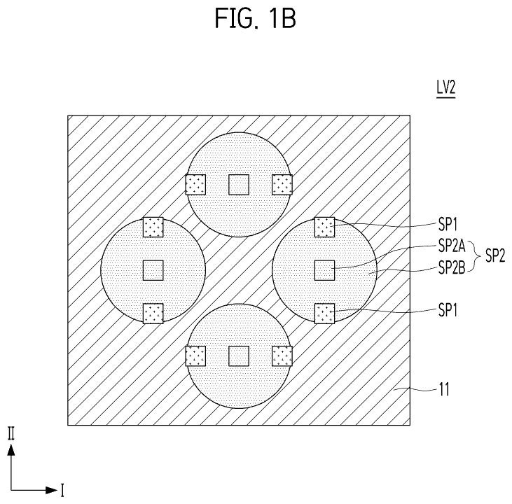

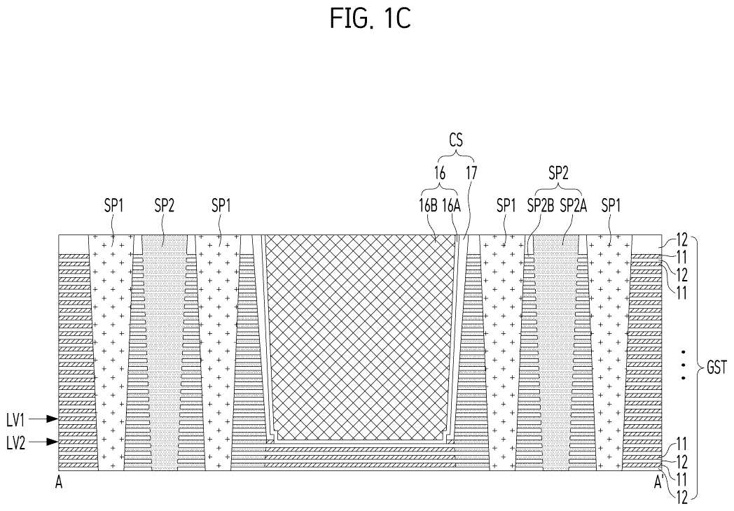

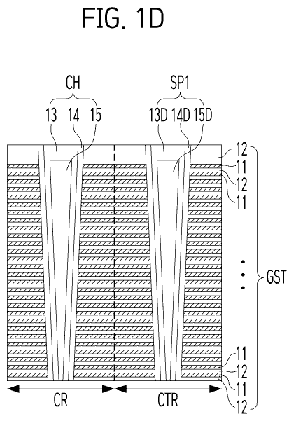

FIG. 1A to FIG. 1D are diagrams illustrating the structure of a semiconductor device in accordance with an embodiment. FIG. 1A is a plan view at a first level LV1 of a contact region CTR, FIG. 1B is a plan view at a second level LV2 of the contact region CTR, FIG. 1C is a cross-sectional view taken along line A-A′ of FIG. 1A, and FIG. 1D is a cross-sectional view of a cell region CR and the contact region CTR.

Referring to FIG. 1A to FIG. 1D, the semiconductor device includes a gate structure GST, a contact structure CS, first supports SP1, and second supports SP2. The semiconductor device includes a channel structure CH.

The gate structure GST includes conductive layers 11 alternately stacked with insulating layers 12. The conductive layers 11 include gate lines such as source select lines, word lines, or drain select lines. The conductive layers 11 may include a conductive material such as polysilicon, tungsten, or molybdenum. The insulating layers 12 insulate consecutive stacked conductive layers 11 from each other, and may include oxide, nitride, air gap, or the like.

The gate structure GST includes the cell region CR and the contact region CTR. The channel structure CH is located in the cell region CR, and the contact structure CS, the first supports SP1, and the second supports SP2 are located in the contact region CTR.

A first figure or shape F1 and a second figure or shape F2 are shown on an upper surface of the gate structure GST in FIG. 1A to facilitate description of the relationships between the locations of first supports SP1, second supports SP2, and a contact structure CS. The first figure F1 and the second figure F2 do not form part of the semiconductor device. For example, the first figure F1 is a two-dimensional figure such as a circle or a polygon. The first figure F1 is a circle with the center of the contact structure CS at the center of the first figure F1 and having a radius equal to a first distance D1. The center of the first figure F1 may be referred to as a point on the gate structure GST. The centers of the second supports SP2 are located along a perimeter of the first figure F1. The second support SP2 includes a pillar SP2A and protrusions SP2B. The pillar SP2A is located at the perimeter of the first figure F1 and extends through the gate structure GST as shown in the example of FIG. 1C. For example, the center of the pillar SP2A is spaced apart from the center of the contact structure CS by the first distance D1. The protrusions SP2B extend between the pillar SP2A and the conductive layers 11. For example, the protrusions SP2B extend to a second distance D2 from the center of the pillar. The first distance D1 is greater than the second distance D2 in this example. The second supports SP2 may each include an insulating material such as oxide.

The second figures F2 may be a two-dimensional figure such as circles or polygons. The second figure F2 is a circle with the center of the second support SP2 at the center of the second figure F2 and having a radius equal to the second distance D2. The centers of the second figures F2 are arranged along the perimeter of the first figure F1 and are spaced apart in the example. The protrusions SP2B may correspond to the second figures F2.

The centers of the pillars SP2A are located at the centers of the second figures F2. The first supports SP1 are located primarily inside the second figures F2. The centers of the first supports SP1 are located less than the second distance D2 from the centers of the second supports SP2. For example, the majority of the area of the first supports SP1 is located inside the second figure F2. The first supports SP1 are at least partially surrounded by the protrusions SP2B and extend through the gate structure GST. Each of the plurality of first supports SP1 is located within the second distance D2 of the center of one of the second supports SP2. For example, the first supports SP1 include dummy channel structures.

The contact structure CS is located inside the first figure F1 and extends through the gate structure GST. For example, the center of the contact structure CS is located at the center of the first figure F1 as shown in FIG. 1A. The contact structure CS is electrically connected to a first conductive layer 11 of the conductive layers 11. The contact structure CS includes a contact plug 16 electrically connected to the first conductive layer 11 and an insulating spacer 17 surrounding outer sidewalls of the contact plug 16. The contact plug 16 includes a barrier layer 16A adjacent to the insulating spacer 17 and a metal layer 16B surrounded by the barrier layer 16A. The barrier layer 16A may include metal nitride. The semiconductor device includes a plurality of contact structures CS, and one of the contact structures CS is connected to a different one of the conductive layers 11. An outer perimeter of the contact structure CS is located within the second distance D2 from the center of one or more of the second supports SP2.

The second figures F2 are spaced apart and located around the periphery of the contact structure CS. The second figures F2 may overlap with the contact structure CS. The second supports SP2 are located around the contact structure CS. A subset of the protrusions SP2B extending between the pillar SP2A and the contact structure CS contacts the contact structure CS. For example, the protrusions SP2B may contact the insulating spacer 17.

The channel structure CH extends through the gate structure GST in the cell region CR. The channel structure CH includes a channel layer 13, a memory layer 14 surrounding the channel layer 13, and an insulating core 15 located within and surrounded by the channel layer 13. The memory layer 14 includes at least one of a tunneling layer, a data storage layer, and a blocking layer. The data storage layer may include a floating gate, polysilicon, a charge trap material, nitride, a phase change material, or the like.

The first support SP1 includes a dummy channel structure. For example, the first support SP1 includes a dummy channel layer 13D, a dummy memory layer 14D surrounding the dummy channel layer 13D, and a dummy insulating core 15D located within and surrounded by the dummy channel layer 13D.

As described, the first supports SP1 and the second supports SP2 are located around the periphery of the contact structure CS. The first supports SP1 are located around the periphery of second supports SP2. Accordingly, the gate structure GST may be stably supported by the first supports SP1 and the second supports SP2.

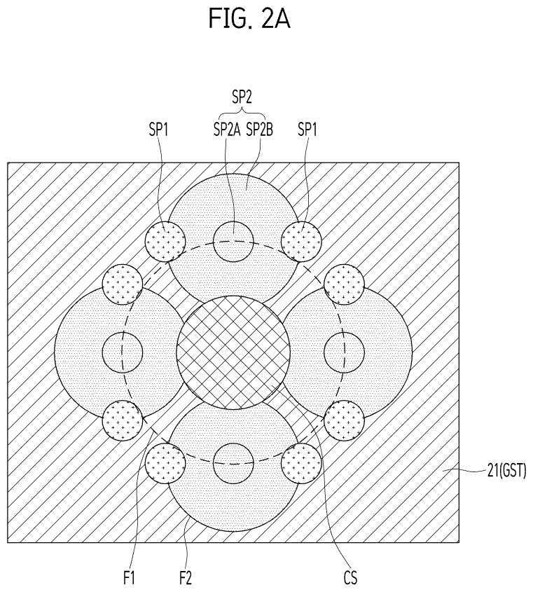

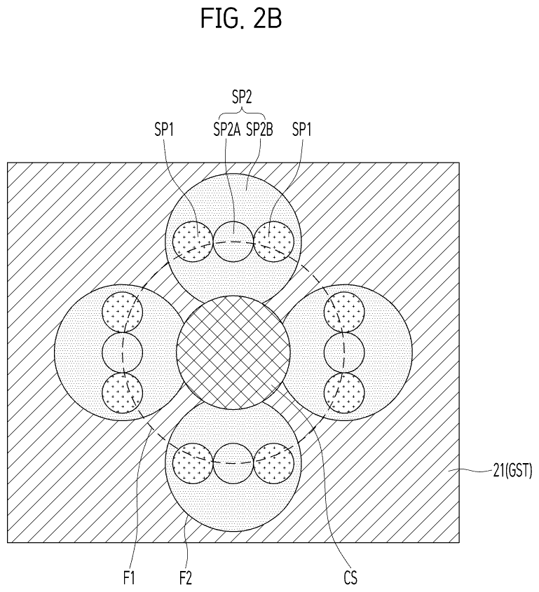

FIG. 2A and FIG. 2B are plan views illustrating the structure of a semiconductor device in accordance with an embodiment.

Referring to FIG. 2A and FIG. 2B, the semiconductor device includes a gate structure GST, a contact structure CS, first supports SP1, and second supports SP2. The gate structure GST includes stacked conductive layers 21, and the contact structure CS is electrically connected to one conductive layer of the conductive layers 21. The second support SP2 includes a pillar SP2A and protrusions SP2B.

Referring to FIG. 2A, a first figure F1 is a circle, and the center of the contact structure CS is located at the center of the first figure F1 or a point on the gate structure GST. The centers of the pillars SP2A are arranged along a perimeter of the first figure F1. For example, the centers of the pillars SP2A are located at the perimeter of the first figure F1 in an embodiment. Alternatively, the centers of the pillars SP2A may be located either inside or outside the perimeter of the first figure F1 and at least a section of the pillars SP2A is located inside the first figure F1. For example, the center of the first support SP1 may be located at the perimeter of the first figure F1. Alternatively, the centers of the first supports SP1 may be located either inside or outside the perimeter of the first figure F1, and a at least a section of the first supports SP1 is located inside the first figure F1. In an embodiment, each of the second figures F2 includes two first supports SP1 and a second support SP2 formed such that the centers of the two first supports SP1 and the center of the second support SP2 form a line tangent to and outer perimeter of the first figure F1.

The second figure F2 is a circle, and the center of each pillar SP2A is located at the center of one of the second figures F2 in this example. The first supports SP1 are arranged along a perimeter of the second figure F2. For example, the centers of the first supports SP1 are located at the perimeter of the second figure F2. Alternatively, the centers of the first supports SP1 may be located either inside or outside the perimeter of the second figure F2, and at least a section of the first supports SP1 is located inside the second figure F2.

At least one first support SP1 is located at least partially inside the second figure F2. For example, two first supports SP1 may be located at least partially inside each second figure F2. The first supports SP1 are located symmetrically with respect to the pillar SP2A inside the second figure F2 in the example of FIG. 2A. For example, a first of the two first supports SP1 is located near a first side of the pillar SP2A and a second of the two first supports SP1 is located near a second or opposite side of the pillar SP2A. The centers of the first supports SP1 and the pillar SP2A may be arranged in a line. The quantity of first supports SP1 located inside the second figure F2 may be determined based on structural stability characteristics or parameters of the semiconductor device. Three or more first supports SP1 may be located at least partially inside the second figure F2.

Referring to FIG. 2B, the first supports SP1 are located entirely inside the second figure F2 in this example. The first supports SP1 do not extend beyond the perimeter of the second figure F2 and are located close to the pillar SP2A. For example, the first supports SP1 may contact the pillar SP2A within each second figure F2.

The quantities of first supports SP1 and the second supports SP2 and an arrangement of the first supports SP1 and the second supports SP2 may be determined based on structural stability characteristics or parameters of the semiconductor device. Locating the first supports SP1 entirely inside the second figure F2 may improve the structural stability of the semiconductor device.

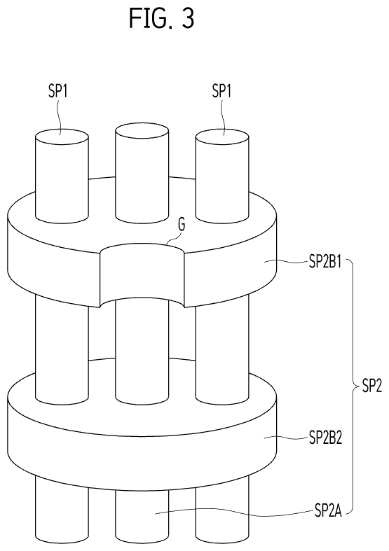

FIG. 3 is a perspective view illustrating the structure of a semiconductor device in accordance with an embodiment.

Referring to FIG. 3, the semiconductor device includes two first support SP1 and a second support SP2. The second support SP2 includes a pillar SP2A, a first protrusion SP2B1, and a second protrusion SP2B2. One or more of the first supports SP1 extends through the first protrusion SP2B1 and the second protrusion SP2B2. The protrusions SP2B1 and SP2B2 may be projections or extensions.

The first protrusion SP2B1 contacts a contact structure CS. A groove G is formed in the first protrusion SP2B1 in a region that contacts the contact structure. The second protrusion SP2B2 is located below the contact structure CS and might not contact the contact structure CS. When the second protrusion SP2B2 does not contact the contact structure CS, the second protrusion SP2B2 does not include the groove G. Accordingly, the first protrusion SP2B1 and the second protrusion SP2B2 have different shapes. The second protrusion SP2B2 has a general shape that does not include the groove G. For example, the second protrusion SP2B2 has a symmetrical shape such as a circular shape. The first protrusion SP2B1 has an abnormal shape that includes the groove G and may have an asymmetrical or a symmetrical shape.

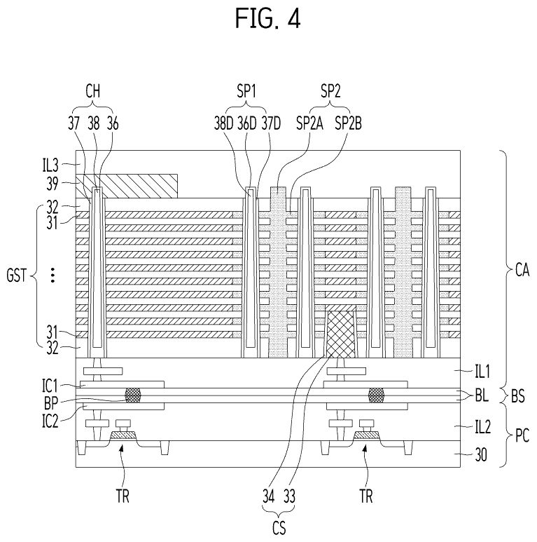

FIG. 4 is a diagram illustrating the structure of a semiconductor device in accordance with an embodiment.

Referring to FIG. 4, the semiconductor device includes a peripheral circuit PC, a bonding structure BS, and a memory cell array CA. The bonding structure BS is located between the peripheral circuit PC and the memory cell array CA.

The memory cell array CA includes a gate structure GST, contact structures CS, first supports SP1, and second supports SP2. The memory cell array CA includes a channel structure CH, a source structure 39, a first interconnection structure IC1, a first interlayer insulating layer IL1, and a third interlayer insulating layer IL3.

The gate structure GST includes conductive layers 31 alternately stacked with insulating layers 32. The source structure 39 is located on the gate structure GST, and the third interlayer insulating layer IL3 is located on the source structure 39. The channel structure CH extends through the gate structure GST and into the source structure 39. The channel structure CH includes a channel layer 36, a memory layer 37 surrounding the channel layer 36, and an insulating core 38 surrounded by the channel layer 36. The first interconnection structure IC1 is connected to at least one of the channel structure CH and the contact structure CS. The first interconnection structure IC1 is located in the first interlayer insulating layer IL1.

The contact structures CS extends through the gate structure GST and is connected to the conductive layers 31. Each of the contact structures CS includes a contact plug 33 and an insulating spacer 34.

The second supports SP2 are located at the periphery of the contact structure CS and extend through the gate structure GST. Each of the second supports SP2 includes a pillar SP2A and a plurality of protrusions SP2B.

The first supports SP1 are located at the sides of the second supports SP2 and extend through the protrusions SP2B. The first supports SP1 include dummy channel structures and may include a dummy channel layer 36D, a dummy memory layer 37D, and a dummy insulating core 38D.

The peripheral circuit PC includes a transistor TR disposed on a substrate 30. For example, the peripheral circuit PC may include a page buffer, a row decoder, a logic circuit, and so forth. A second interconnection structure IC2 is connected to the peripheral circuit PC and is located in a second interlayer insulating layer IL2.

The bonding structure BS is located between the first interlayer insulating layer IL1 and the second interlayer insulating layer IL2. The bonding structure BS includes a bonding layer BL and bonding pads BP. The memory cell array CA is bonded to the peripheral circuit PC by the bonding layer BL. The peripheral circuit PC is electrically connected to the memory cell array CA by the bonding pads BP.

The peripheral circuit PC and the memory cell array CA may be formed by separate manufacturing processes and are connected through the bonding structure BS. The first supports SP1 extend through the protrusions SP2B, resulting in improved structural stability during a manufacturing process.

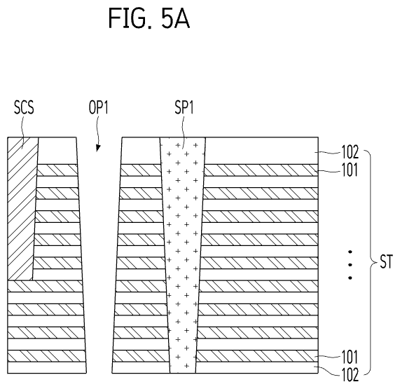

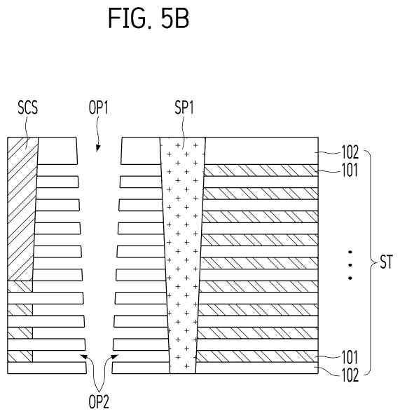

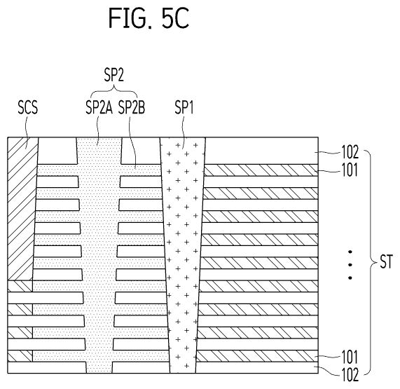

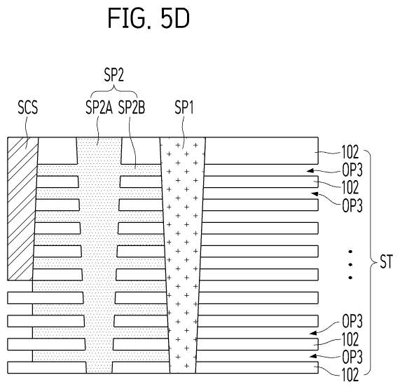

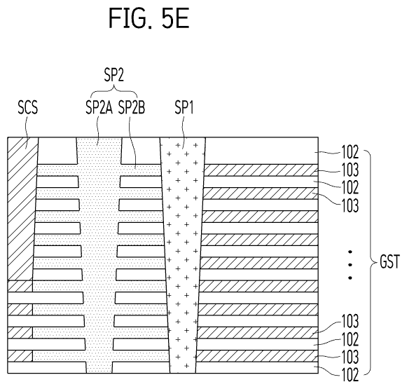

FIG. 5A to FIG. 5E are diagrams illustrating a semiconductor device as formed utilizing a method of manufacturing a semiconductor device in accordance with an embodiment.

Referring to FIG. 5A, a stack ST including first material layers 101 alternately stacked with second material layers 102 is formed. The first material layers 101 form gate lines, for example. The first material layers 101 include a sacrificial material such as nitride or a conductive material such as polysilicon or metal. The second material layers 102 insulate consecutive stacked gate lines from each other. The second material layers 102 include an insulating material such as oxide, nitride, or air gap.

A first support SP1 extending through the stack ST is formed. The first support SP1 may be formed as a single layer or with multiple layers. The first support SP1 includes a material having a high etching selectivity with respect to the etching selectivity of the first material layers 101. When the first support SP1 has multiple layers, the outermost layer includes a material having a high etching selectivity with respect to the etching selectivity of the first material layers 101.

A sacrificial contact structure SCS extending through the stack ST is formed. For example, a plurality of sacrificial contact structures SCS, each connected to a different one of the first material layers 101, is formed. The sacrificial contact structure SCS includes at least one sacrificial layer that is replaced with a contact plug in a subsequent process.

The sacrificial contact structure SCS is formed as a single layer or with multiple layers. The sacrificial contact structure SCS includes a material having a high etching selectivity with respect to the etching selectivity of the first material layers 101. When the sacrificial contact structure SCS includes multiple layers, the outermost layer includes a material having a high etching selectivity with respect to the etching selectivity of the first material layers 101. The sacrificial contact structure SCS may be formed before or after the first support SP1 is formed. A contact structure including a contact plug may be formed instead of the sacrificial contact structure SCS.

A first opening OP1 extending through the stack ST is formed. The first material layers 101 are exposed through the first opening OP1. The first opening OP1 is located near a periphery of the sacrificial contact structure SCS. The first support SP1 is located near a periphery of the first opening OP1.

Referring to FIG. 5B, second openings OP2 are formed by etching the first material layers 101 through the first opening OP1. The first material layers 101 are selectively etched until the first support SP1 and the sacrificial contact structure SCS are exposed. The second openings OP2 are formed to partially expose a sidewall of the first support SP1. The second openings OP2 are formed to partially expose a sidewall of the sacrificial contact structure SCS.

While the first material layers 101 are etched, the first support SP1 supports the remaining second material layers 102. As a result, the occurrence of tilted or collapsed second material layers 102 may be reduced or eliminated. The supporting force is stronger the closer the first support SP1 is located to the first opening OP1. The supporting force is stronger when the quantity of first supports SP1 located around the first opening OP1 is more numerous.

Referring to FIG. 5C, a second support SP2 is formed in the first opening OP1 and the second openings OP2. The second support SP2 includes a pillar SP2A in the first opening OP1 and protrusions SP2B extending from the pillar SP2A into the second openings OP2. The protrusions SP2B partially surround a sidewall of the first support SP1. The protrusions SP2B partially surround or extend around a sidewall of the sacrificial contact structure SCS.

Referring to FIG. 5D, third openings OP3 are formed by removing the first material layers 101. During the process of removing the first material layers 101, the second supports SP2 support the stack ST. For example, the supporting force is increased by the protrusions SP2B of the second support SP2.

Referring to FIG. 5E, third material layers 103 are formed in the third openings OP3. The third material layers 103 form gate lines and are conductive layers. The third material layers 103 alternately stacked with the second material layers 102 form a gate structure GST.

According to the method of manufacturing described, when the second openings OP2 are formed, the stack ST is supported by the first support SP1. When the first material layers 101 are replaced with the third material layers 103, the stack ST is supported by the second support SP2. Accordingly, occurrence of tilted or collapsed layers of the stack ST may be reduced or eliminated.

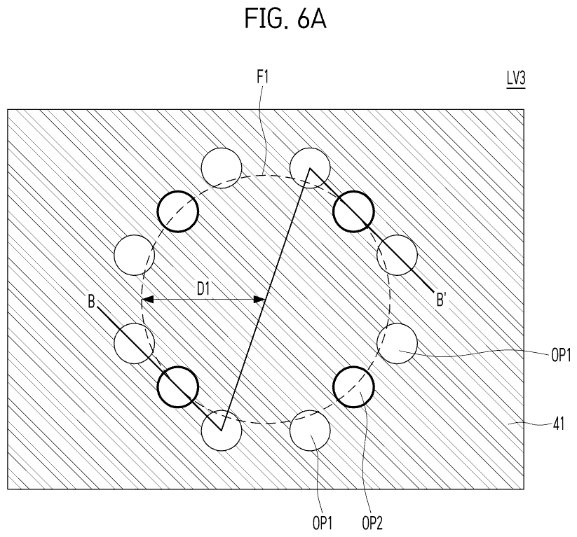

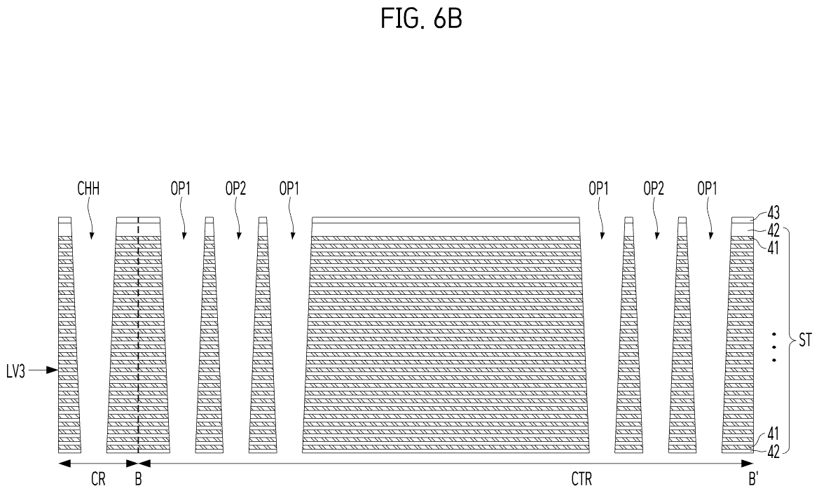

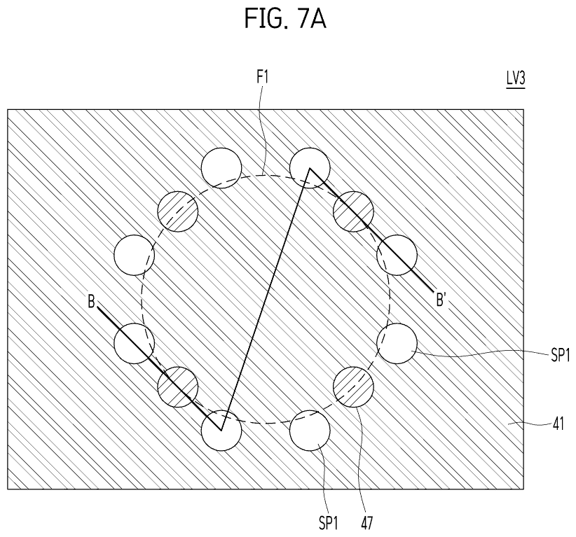

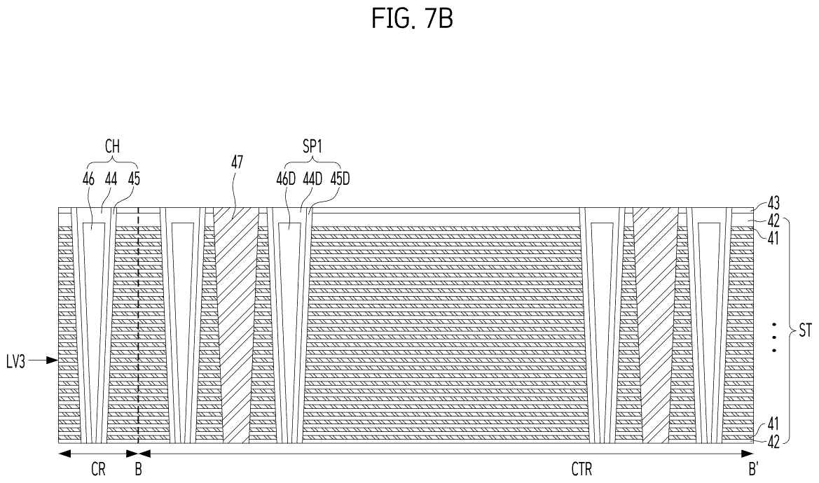

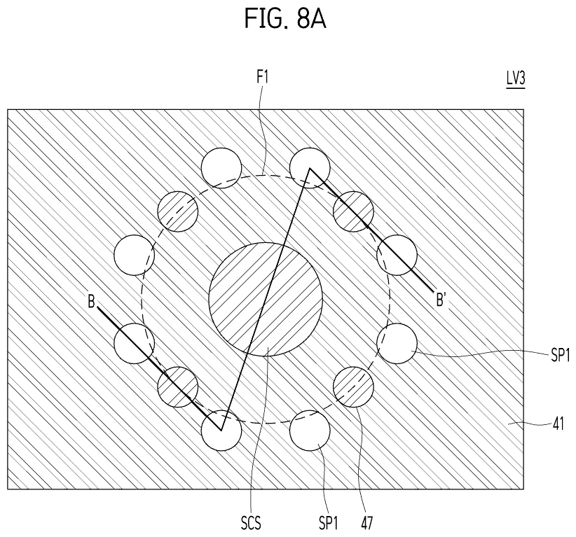

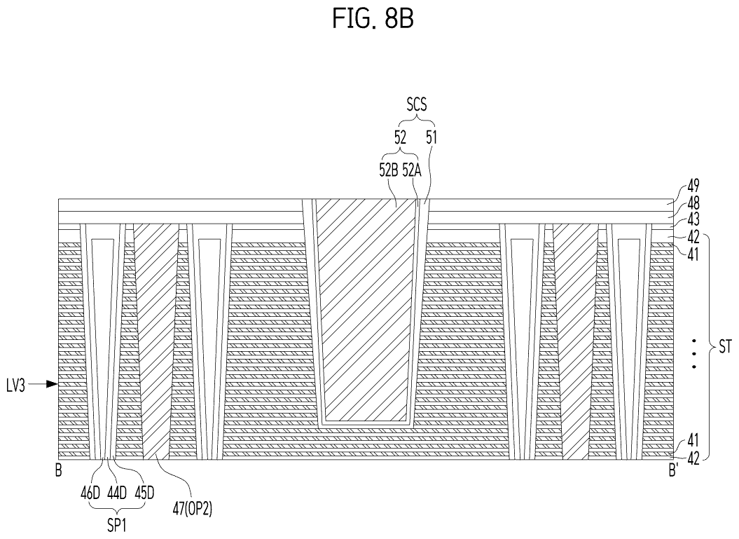

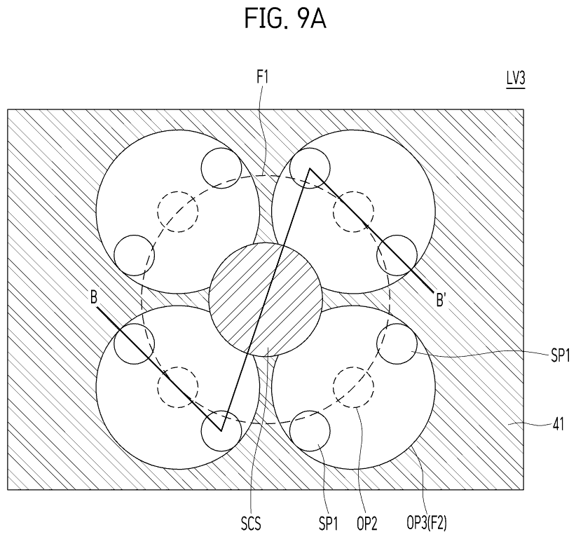

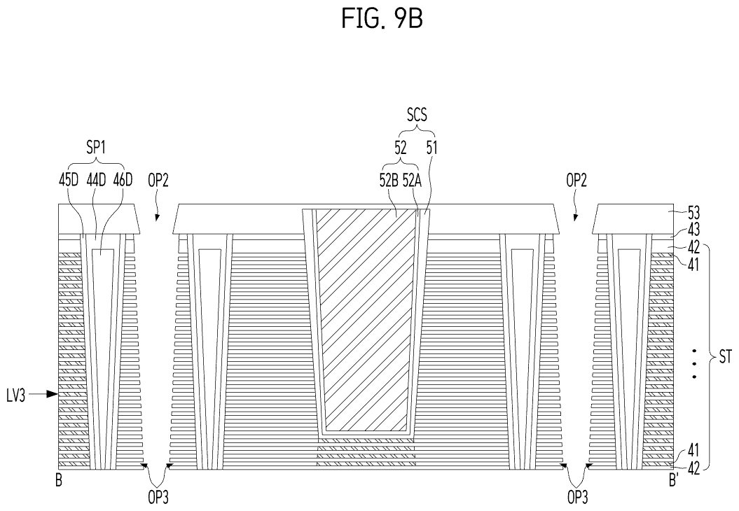

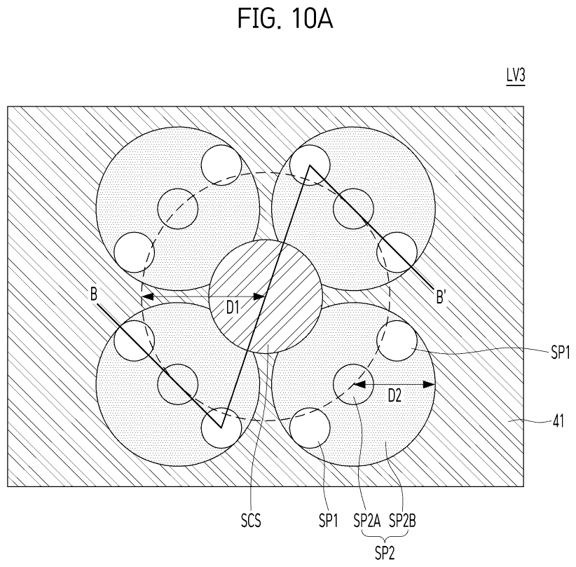

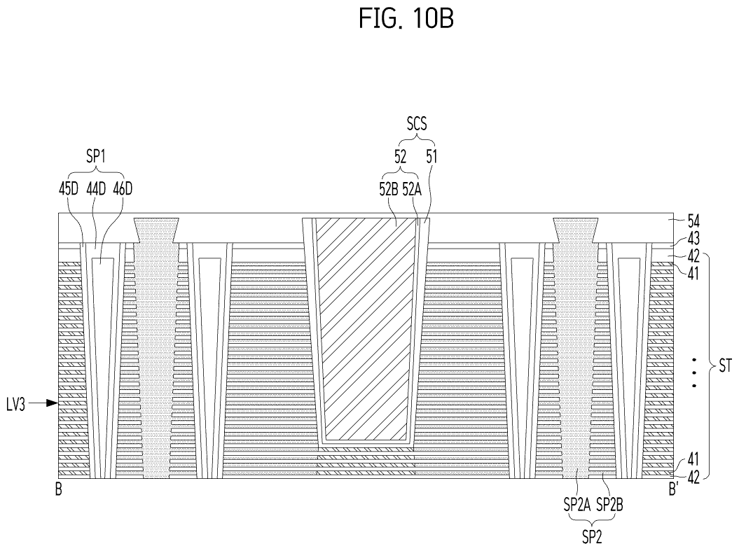

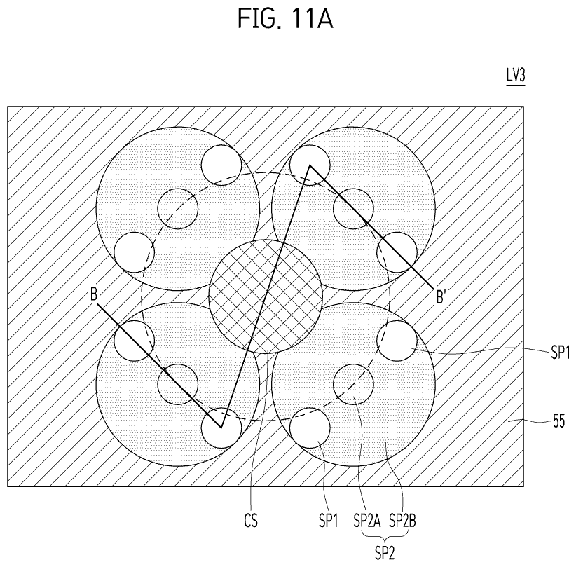

FIG. 6A, FIG. 6B, FIG. 7A, FIG. 7B, FIG. 8A, FIG. 8B, FIG. 9A, FIG. 9B, FIG. 10A, FIG. 10B, FIG. 11A, and FIG. 11B are diagrams illustrating a semiconductor device as formed utilizing a method of manufacturing a semiconductor device in accordance with an embodiment. FIG. 6A, FIG. 7A, FIG. 8A, FIG. 9A, FIG. 10A, and FIG. 11A are plan views at a third level LV3 of the contact region CTR, and FIG. 6B, FIG. 7B, FIG. 8B, FIG. 9B, FIG. 10B, and FIG. 11B are cross-sectional views.

Referring to FIG. 6A and FIG. 6B, a stack ST including first material layers 41 alternately stacked with second material layers 42 is formed. The stack ST includes a cell region CR and a contact region CTR. The first material layers 41 form gate lines. The first material layers 41 include a sacrificial material such as nitride or a conductive material such as polysilicon or metal. The second material layers 42 insulate consecutive stacked gate lines from each other. The second material layers 42 include an insulating material such as oxide, nitride, or air gap.

First openings OP1 are formed in the contact region CTR of the stack ST. For example, a hard mask pattern 43 is formed on the stack ST, and the first openings OP1 are formed by etching the stack ST using the hard mask pattern 43 as an etching barrier. For example, the first openings OP1 are located at a perimeter of the first figure F1 having a radius of the first distance D1 in FIG. 6A, such that a section of the first openings OP1 is located within a first distance D1 of the center of the first figure F1. The centers of the first openings OP1 are located at the perimeter of the first figure F1, or the centers of the first openings OP1 are located either inside or outside the perimeter of the first figure F1. At least a section of the first openings OP1 is located inside the first figure F1. The first openings OP1 may be located entirely inside the first figure F1.

Second openings OP2 are formed in the contact region CTR of the stack ST. For example, the second openings OP2 are formed by etching the stack ST using the hard mask pattern 43 as an etching barrier. The second openings OP2 are located within the first figure F1. For example, the second openings OP2 are located at the perimeter of the first figure F1. The centers of the second openings OP2 are located at the perimeter of the first figure F1 or at a distance D1 from the center of the first figure F1, or the centers of the second openings OP2 are located either inside or outside the perimeter of the first figure F1. For example, each of the second openings OP2 is disposed within the first distance D1 of a center of the first figure F1.

A channel hole CHH is formed in the cell region CR of the stack ST. For example, the channel hole CHH is formed by etching the stack ST using the hard mask pattern 43 as an etching barrier.

The first openings OP1, the second openings OP2, and the channel hole CHH may be formed simultaneously or formed separately or sequentially by individual processes. When the channel hole CHH is formed, the first openings OP1 and the second openings OP2 are formed. The first openings OP1, the second openings OP2, and the channel hole CHH may have substantially the same width and substantially the same depth. When the first openings OP1, the second openings OP2, and the channel hole CHH are formed simultaneously, manufacturing cost may be reduced.

Referring to FIG. 7A and FIG. 7B, sacrificial layers 47 are formed in the first openings OP1, the second openings OP2, and the channel hole CHH. The sacrificial layers 47 include a material having a high etching selectivity with respect to the first material layers 41 and the second material layers 42.

The first openings OP1 and the channel hole CHH are selectively re-opened. For example, a mask pattern covers the second openings OP2 and while the first openings OP1 and the channel hole CHH are formed, and the sacrificial layers 47 in the first openings OP1 and the channel hole CHH are removed.

First supports SP1 are formed in the first openings OP1, and a channel structure CH is formed in the channel hole CHH. The first supports SP1 may be formed when the channel structure CH is formed. The channel structure CH includes a channel layer 44, a memory layer 45, and an insulating core 46. The first support SP1 includes a dummy channel layer 44D, a dummy memory layer 45D, and a dummy insulating core 46D.

Referring to FIG. 8A and FIG. 8B, an insulating layer 48 and a hard mask pattern 49 are formed on the stack ST. A contact hole CTH extending into or within the stack ST through the hard mask pattern 49 and the insulating layer 48 is formed. For example, a plurality of contact holes CTH exposing the first material layers 41is formed. The contact hole CTH is located inside the first figure F1 in this example. For example, the center of the contact hole CTH is located at the center of the first figure F1, which center is referred to as a point on the stack ST.

A sacrificial contact structure SCS is formed in the contact hole CTH. For example, an insulating liner 51 is formed in the contact hole CTH, and a sacrificial layer 52 is formed within the insulating liner 51. The sacrificial layer 52 includes a barrier layer 52A and a sacrificial metal layer 52B. The barrier layer 52A may include metal nitride.

Referring to FIG. 9A and FIG. 9B, the second openings OP2 are re-opened. For example, the hard mask pattern 49 is removed, and an insulating layer 53 is formed. The insulating layer 53 includes the insulating layer 48. The second openings OP2 are exposed by etching the insulating layer 53, and the sacrificial layers 47 are removed.

Third openings OP3 are formed by etching the first material layers 41 through the second openings OP2. The third openings OP3 are spaced apart in a vertical direction with respect to FIG. 9B, for example, from a first end of the stack ST to an opposite end of the stack ST. The third openings OP3 are arranged along and extend from the openings OP2, are centered about the center of the second opening OP2, and extend between the sacrificial contact structure SCS and the second openings OP2 as shown in the example of FIG. 9A. The outer perimeter of the third openings OP3 may correspond to the perimeter of the second figure F2. The first supports SP1 and the sacrificial contact structure SCS are exposed through the third openings OP3. Regions where the first material layers 41 are removed from the third openings OP3, which regions may correspond to the second figures F2. The second figures F2 are spaced apart and arranged along the perimeter of the first figure F1, and the centers of the second figures F2 are located on the perimeter of the first figure F1 in this example. A set of the third openings OP3 surrounds one of the second openings OP2.

The second figure F2 overlaps with the sacrificial contact structure SCS, and the outer perimeters of the first supports SP1 are located within the second figure F2 as shown in the example of FIG. 9A. During the process of forming the third openings OP3, the second material layers 42 are supported by the first supports SP1, and structural stability may be increased.

Referring to FIG. 10A and FIG. 10B, second supports SP2 are formed in the second openings OP2 and the third openings OP3. For example, the second supports SP2 are formed by filling the second openings OP2 and the third openings OP3 with an insulating material such as an oxide or nitride and performing a planarization process. The second support SP2 includes a pillar SP2A in the second opening OP2 and protrusions SP2B extending from the pillar SP2A in the third openings OP3. As shown in the example of FIG. 10A, each of the second supports SP2 includes a pillar SP2A surrounded by a set of protrusions SP2B, and different sets of protrusions SP2b are spaced apart or do not overlap. A set of protrusions SP2B at least partially surrounds one or more first supports SP1. Thus, the first supports SP1 are located within a second distance D2 of the center of a second support SP2, and the centers of the second supports SP2 are located at the first distance D1 from the center of the sacrificial contact structure SCS as shown in the example of FIG. 10A. An insulating layer 54 is formed.

Referring to FIG. 11A and FIG. 11B, the first material layers 41 are replaced with third material layers 55. For example, a slit is formed in the stack ST, and the first material layers 41 are removed through the slit (not shown). The third material layers 55 are formed in regions where the first material layers 41 are removed. The third material layers 55 are used to form gate lines and may include metal such as tungsten or molybdenum. The third material layers 55 alternately stacked with the second material layers 42 form a gate structure GST. Alternatively, when the first material layers 41 include a conductive material, the first material layers 41 do not undergo a replacement process. In this example, the first material layers 41 form the gate lines, and the stack ST is the gate structure GST.

The sacrificial contact structure SCS is exposed by etching the insulating layer 54, and the sacrificial layer 52 is removed. An insulating spacer 51A is formed by etching the insulating liner 51, and the third material layer 55 is exposed through an opening at a bottom of the insulating spacer 51A. A contact plug 56 may be formed within the insulating spacer 51A. For example, a barrier layer 56A is formed adjacent to the insulating spacer 51A, and a metal layer 56B is formed within the barrier layer 56A. The contact plug 56 is formed by planarizing the metal layer 56B and the barrier layer 56A. During a planarizing process, the insulating layer 54 is partially etched, and the second supports SP2 are exposed. As shown in the example of FIG. 11A, the center of the contact structure CS is located equidistantly to a center of each of the second supports SP2, and the centers of the second supports SP2 are equidistantly spaced apart, for example, equally angularly spaced, such as 90 degree spacing, relative to the center of the contact structure CS.

When the third openings OP3 are formed, the second material layers 42 are supported by the first supports SP1. Accordingly, tilted or collapsed second material layers 42 are reduced or eliminated during a manufacturing process, and structural stability may be improved.

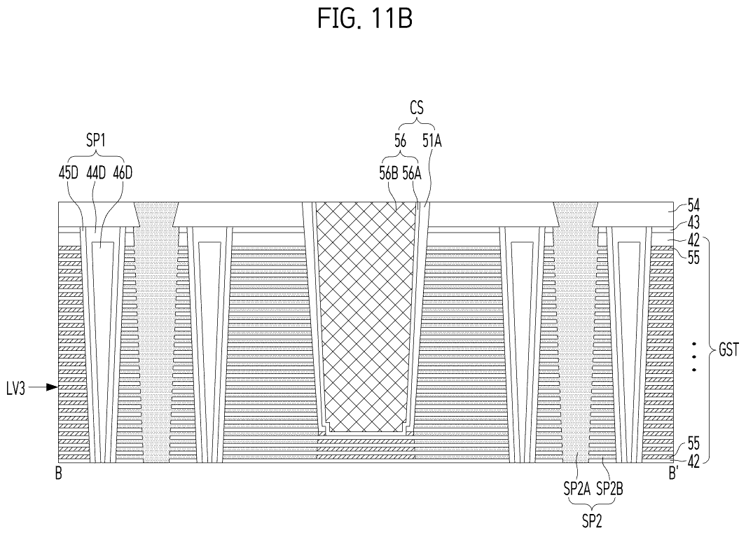

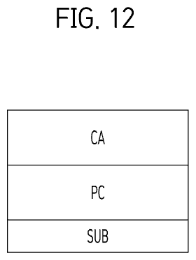

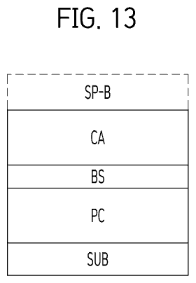

The structure and the manufacturing method according to the described embodiments may be applied to semiconductor devices including various structures. FIG. 12 and FIG. 13 illustrate example configurations of a semiconductor device to which the described embodiments are applicable.

FIG. 12 is a configuration diagram of a semiconductor device according to an embodiment of the present disclosure.

Referring to FIG. 12, the semiconductor device includes a substrate SUB, a peripheral circuit PC, and a memory cell array CA. In this example, the peripheral circuit PC and the memory cell array CA are formed on or over the same substrate.

The substrate SUB may be made of or include a semiconductor material. In an embodiment, the semiconductor material may include at least one of a group IV semiconductor, a group III-V compound semiconductor, and a group II-VI compound semiconductor. The group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AIAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC is disposed between the substrate SUB and the memory cell array CA. The peripheral circuit PC includes a row decoder, a column decoder, a page buffer, a logic circuit, a control circuit, a sense amplifier, an input/output circuit, and the like in this example. In an embodiment, the peripheral circuit PC may include an NMOS transistor, a PMOS transistor, a resistor, a capacitor, and the like. The peripheral circuit PC includes an interconnection structure. The interconnection structure includes a path that transfers an operation voltage and may include a contact plug, a line, and the like.

The memory cell array CA includes memory cells. In an embodiment, the memory cell array CA includes memory strings connected between a source line and a bit line, and the memory strings may include stacked memory cells. In an embodiment, the memory cell array CA includes memory cells connected between a word line and a bit line. The memory cell array CA includes an interconnection structure.

FIG. 13 is a configuration diagram of a semiconductor device according to an embodiment of the present disclosure.

Referring to FIG. 13, the semiconductor device includes a substrate SUB, a peripheral circuit PC, a bonding structure BS, and a memory cell array CA. The peripheral circuit PC and the memory cell array CA are formed on separate substrates and bonded. The semiconductor device includes a support base SP-B.

The substrate SUB is used as a support during a process including forming the peripheral circuit PC. The support base SP-B is used as a support during a process including forming the memory cell array CA. In an embodiment, after manufacturing a first wafer including the memory cell array CA and a second wafer including the peripheral circuit PC, the first wafer and the second wafer are electrically connected by the bonding structure BS. At least some of the support base SP-B of the first wafer may be removed. The support base SP-B may be completely removed or may partially remain on the memory cell array CA.

The support base SP-B may be a semiconductor substrate, an insulating substrate, a silicon-on-insulator (SOI) substrate, a germanium-on-insulator (GeOI) substrate, or the like. The support base SP-B may be a bulk wafer, an epitaxial layer grown in a selective epitaxial growth (SEG) method, or a layer formed in a metal induced lateral crystallization (MILC) method. The support base SP-B may have a single crystalline, polycrystalline, or amorphous state. The support base SP-B may include an impurity of group II, group III, group IV, group V, or group VI.

The bonding structure BS connects the memory cell array CA and the peripheral circuit PC. The memory cell array CA and the peripheral circuit PC may be bonded utilizing a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or a metal alloy. The bonding interface may include a non-metal-non-metal interface, a metal-metal interface, or the like. The memory cell array CA and the peripheral circuit PC are electrically connected by the bonding structure BS.

An interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. As a result, contact plugs, lines, and the like formed on different wafers may be electrically connected without a separate bonding pad.

Other configurations similar to the configurations described with reference to FIG. 12 and FIG. 13 may be utilized.

The semiconductor device may have a structure in which the embodiments described with reference to FIG. 12 and FIG. 13 are combined or may have a partially modified structure. In the embodiment described with reference to FIG. 12 and FIG. 13, positions of the memory cell array CA and the peripheral circuit PC may be changed. At least one memory cell array CA and/or at least one peripheral circuit PC may be bonded to the configurations described with reference to FIG. 12 and FIG. 13. In an embodiment, a section of the peripheral circuitry PC may be disposed in the memory cell array CA.

Although the detailed embodiments are described in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a gate structure including conductive layers and insulating layers that are alternately stacked;
second supports each including a pillar located at a perimeter of a first figure defined on an upper surface of the gate structure and protrusions extending from sidewalls of the pillar toward the conductive layers;
a contact structure extending through the gate structure inside the first figure and electrically connected to one of the conductive layers; and
first supports penetrating through the protrusions.

2. The semiconductor device of claim 1, wherein second figures are defined on the upper surface of the gate structure by the protrusions, and the pillar is located at a center of each of the second figures.

3. The semiconductor device of claim 2, wherein the second figures are arranged along the perimeter of the first figure, and are spaced apart from each other.

4. The semiconductor device of claim 2, wherein the first supports are located inside the second figures.

5. The semiconductor device of claim 2, wherein, in each of the second figures, the first supports are located symmetrically to each other with respect to the pillar.

6. The semiconductor device of claim 2, wherein each of the second figures overlaps with the contact structure.

7. The semiconductor device of claim 1, wherein the contact structure is located at a center of the first figure.

8. The semiconductor device of claim 1, wherein the contact structure comprises:
a contact plug electrically connected to the one conductive layer; and
an insulating spacer surrounding sidewalls of the contact plug.

9. The semiconductor device of claim 1, wherein protrusions extending toward the contact structure among the protrusions are in contact with the contact structure.

10. The semiconductor device of claim 1, wherein the protrusions arranged along the perimeter of the first figure are spaced apart from each other.

11. The semiconductor device of claim 1, further comprising a channel structure extending through the gate structure.

12. The semiconductor device of claim 11, wherein each of the first supports is a dummy channel structure.

13. A semiconductor device comprising:
a gate structure including conductive layers and insulating layers that are alternately stacked;
a contact structure extending through the gate structure and electrically connected to one of the conductive layers;
second supports each including a pillar extending through the gate structure and located to be spaced apart from the contact structure by a first distance and protrusions extending from a center of the pillar toward the conductive layers by a second distance; and
first supports located within the second distance from the second supports.

14. The semiconductor device of claim 13, wherein protrusions of adjacent second supports of the second supports are spaced apart from each other.

15. The semiconductor device of claim 13, wherein the first supports penetrate through the protrusions.

16. The semiconductor device of claim 13, wherein the second supports are arranged along a perimeter of a first circle having the contact structure as a center and having a radius of the first distance.

17. The semiconductor device of claim 13, wherein the first supports are located inside a second circle having each of the second supports as a center and having a radius of the second distance.

18. The semiconductor device of claim 17, wherein the second circle overlaps with the contact structure.

19. A semiconductor device comprising:
a gate structure including conductive layers alternately stacked with insulating layers;
a contact structure extending within the gate structure and electrically connected to one of the conductive layers;
second supports, each including a pillar having a center located within a first distance of a center of the contact structure and protrusions extending between the pillar and the conductive layers; and
first supports at least partially surrounded by the protrusions.

20. The semiconductor device of claim 19, wherein the pillar is located at a center of each of the protrusions.

21. The semiconductor device of claim 19, wherein the second supports are spaced apart from each other.

22. The semiconductor device of claim 19, wherein each of the first supports is located within a second distance of the center of one of the second supports, and wherein the first distance is greater than the second distance.

23. The semiconductor device of claim 19, wherein the center of the contact structure is located equidistantly to a center of each of the second supports.

24. A semiconductor device comprising:
a gate structure including conductive layers alternately stacked with insulating layers;
a contact structure extending within the gate structure and electrically connected to one of the conductive layers;
second supports, each including a pillar spaced apart from the contact structure by a first distance and including protrusions extending between the pillar and the conductive layers, wherein the pillar extends through the gate structure and the protrusions extend to a second distance from a center of the pillar; and
first supports located within the second distance of one of the second supports.

25. The semiconductor device of claim 24, wherein the protrusions are arranged around the contact structure and spaced apart from each other.

26. The semiconductor device of claim 24, wherein a set of the protrusions at least partially surrounds one or more of the first supports.
